(19) United States
(12) Patent Application Publication
(10) Pub. No.: US 2007/0247799 A1
(43) Pub. Date: Oct. 25, 2007

(54) COVERING ASSEMBLY FOR CABLE AND NOTEBOOK COMPUTER USING THE SAME

(75) Inventors: ZHI-DONG NIE, Shenzhen (CN); HSUAN-CHEN CHEN, Tu-Cheng (TW); CHIEN-LI TSAI, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/693,696

(22) Filed: Mar. 29, 2007

(30) Foreign Application Priority Data
Apr. 21, 2006 (CN) 200620200397.X

(51) Int. Cl. G06F 1/16; H05K 5/00

(52) U.S. Cl. 361/683; 361/679

(57) ABSTRACT

A covering assembly includes a base and a cover slidably mating with the base. The base includes a cavity bounded by a plurality of sidewalls, at least one slide-rail set on the sidewalls, a hole defined in at least one of the sidewalls, for allowing cables to extend therethrough, and a protrusion set on the at least one slide-rail. The cover includes a coping for covering the cavity, at least one fixing portion set on one side of the coping, configured for slidably engaging with the at least one slide-rail, and a gap defined in the at least one fixing portion configured for engaging with the protrusion to prevent the cover withdrawing from the base. A notebook computer incorporating the covering assembly is also disclosed.

### BACKGROUND OF THE INVENTION

1. Field of the Invention

The present invention generally relates to covering assemblies. Particularly, the present invention relates to a covering assembly for cables of a notebook computer.

2. Description of Related Art

Generally, a portable computer, such as a notebook computer, a laptop, or a personal digital assistant (PDA), has a base and a lid pivotably connected to the base. The base has a central processing unit (CPU), a memory, a controller, and other I/O devices fixed therein, and the lid has a display screen fixed therein.

Usually, the base and the lid are connected to each other with a hinge. Cables are provided to connect the controller in the base and the display screen with each other. Signals sent from the controller are thus transmitted to the display screen via the cables. The cables are also used for providing power to the display screen. However, this structure suffers greatly from its bad appearance in that the cables are exposed to users, and are at risk of being damaged.

Therefore, a covering assembly for shielding the cables is needed in the industry.

### SUMMARY OF THE INVENTION

A covering assembly includes a base and a cover slidably mating with the base. The base includes a cavity bounded by a plurality of sidewalls, at least one slide-rail set on the sidewalls, a hole defined in at least one of the sidewalls, for allowing cables to extend therethrough, and a protrusion set on the at least one slide-rail. The cover includes a coping for covering the cavity, at least one fixing portion set on one side of the coping, configured for slidably engaging with the at least one slide-rail, and a gap defined in the at least one fixing portion configured for engaging with the protrusion to prevent the cover withdrawing from the base.

A notebook computer includes a main body, a lid pivotally connecting with the main body, a plurality of electric cables for communicating the lid with the main body, and a covering assembly fixed on one side of the main body, for receiving and shielding the cables. The covering assembly includes a base having a cavity with a sidewall therearound, a hole being defined in the sidewall configured for allowing the cables to extend therethrough, the base being fixed on one side of the main body; and a cover configured for shielding the cavity slidably mated with the base.

A notebook computer includes a main body, a lid connected to one side of the main body and being pivotable with respect to the main body in an axial direction, a plurality of electric cables for communicating the lid with the main body, a base being cooperatively constituted by the main body and the lid at said side, the base having a cavity configured for receiving the cables therein, and a cover configured for shielding the cavity and slidably attached to the base in the axial direction.

Other systems, methods, features, and advantages of the present covering assembly and notebook computer will be or become apparent to one with skill in the art upon examination of the following drawings and detailed description. It is intended that all such additional systems, methods, features, and advantages be included within this description, be within the scope of the present system and method, and be protected by the accompanying claims.

### BRIEF DESCRIPTION OF THE DRAWINGS

Many aspects of the present covering assembly and notebook computer can be better understood with reference to the following drawings. The components in the drawings are not necessarily to scale, emphasis instead being placed upon clearly illustrating the principles of the inventive system and method. Moreover, in the drawings, like reference numerals designate corresponding parts throughout the several views.

FIG. 1 is an assembled, isometric view of an exemplary embodiment of a notebook computer incorporating a covering assembly in accordance with an exemplary embodiment, the covering assembly including a base and a top cover.

FIG. 2 is a partially exploded, isometric view of part of the notebook computer in FIG. 1.

FIG. 3 is a partially exploded, isometric view of part of the notebook computer in FIG. 1, the notebook computer includes a speaker.

FIG. 4 is an enlarged, inverted view of the cover of the covering assembly.

FIG. 5 is an enlarged view of the cover, viewing from another aspect.

FIG. 6 is an enlarged view of a circled portion VI in FIG. 2.

FIG. 7 is a cross-sectional view of the covering assembly taken along Line VII-VII of FIG. 6.

### DETAILED DESCRIPTION OF THE INVENTION

Reference will now be made to the drawings to describe a preferred embodiment of the present covering assembly and notebook computer.

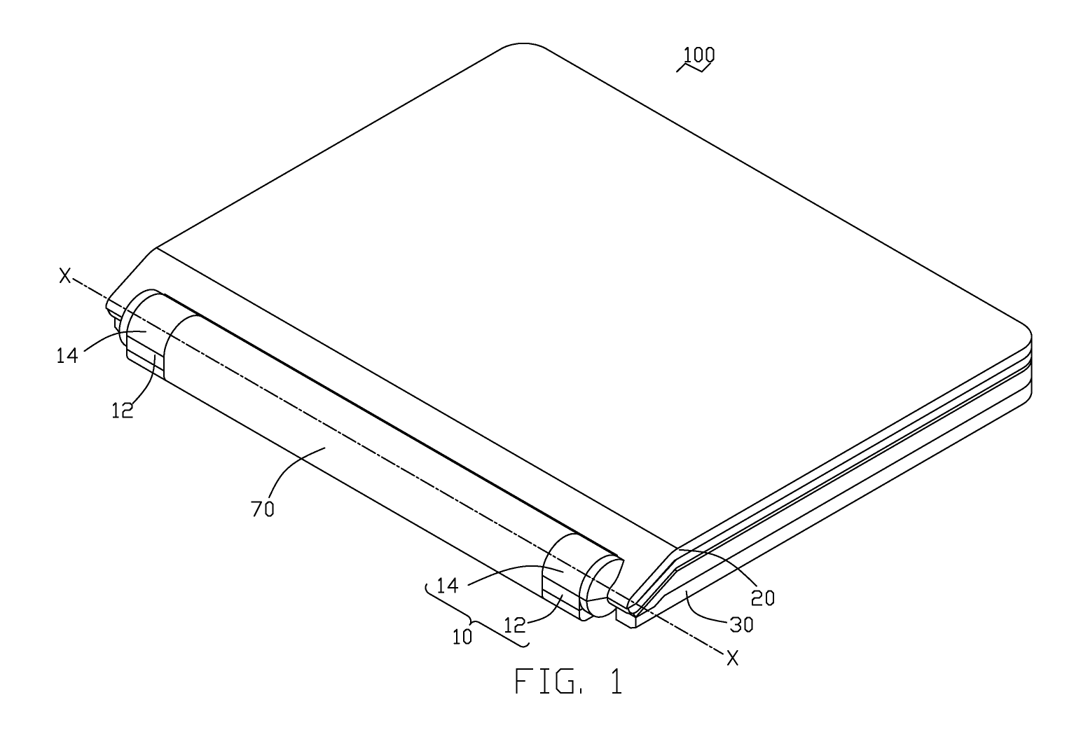

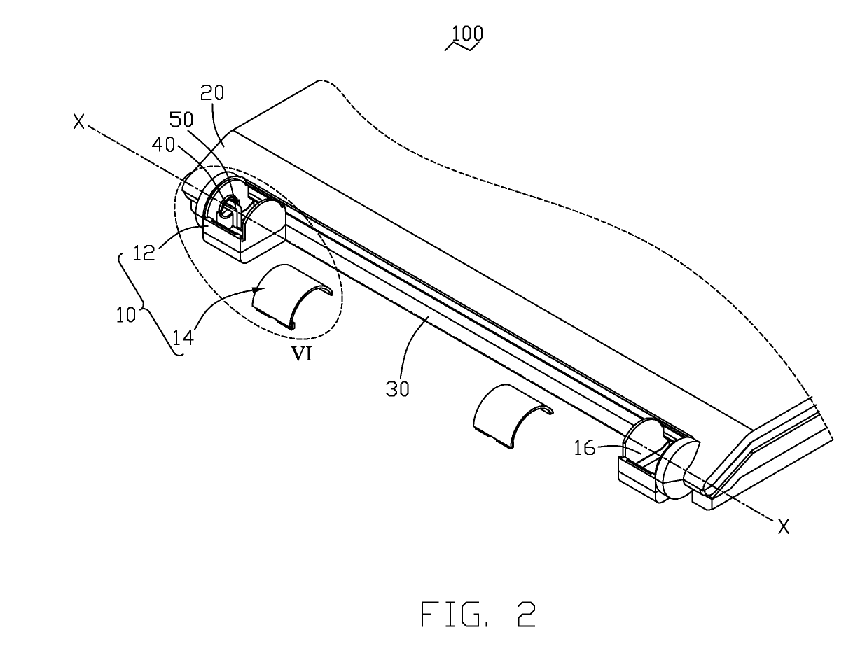

Referring to FIG. 1 and FIG. 2, a notebook computer 100 includes a lid 20 and a main body 30. A display screen (not shown) can be fixed to the lid 20, and controllers and memory devices (not shown) can be fixed in the main body 30. Two hinges 40 as shown in FIG. 2 are symmetrically secured at one side of the main body 30 and the lid 20 to pivotably connect to the lid 20 and the main body 30. The lid 20 is rotatable with respect to the main body 30 around an axial direction X-X to expose or conceal the main body 30. Cables 50 electrically connect the lid 20 and the main body 30 with each other for communication between the lid 20 and the main body 30. The hinges 40 define a through hole (not labeled), for allowing the cables 50 to extend through the hinge 40.

Two covering assemblies 10 are located on the same side of the main body 30 where the hinges 40 are located. Each covering assembly 10 shields the corresponding hinge 40 and the cables 50, thus preventing the cables 50 from being damaged. The covering assembly 10 includes a base 12 and a cover 14. Preferably, one portion of the base 12 is integrally formed with the main body 30 beside the hinge 40 and the other portion is integrally formed with the lid 20. The base 12 has a cavity 16 defined therein, the cavity 16 is used for receiving the cables 50 and the hinge 40. The axial direction X-X extends through the base 12. After the covers 14 are attached to the bases 12, a battery 70 may be mounted to the main body 30 between the covering assemblies 10.

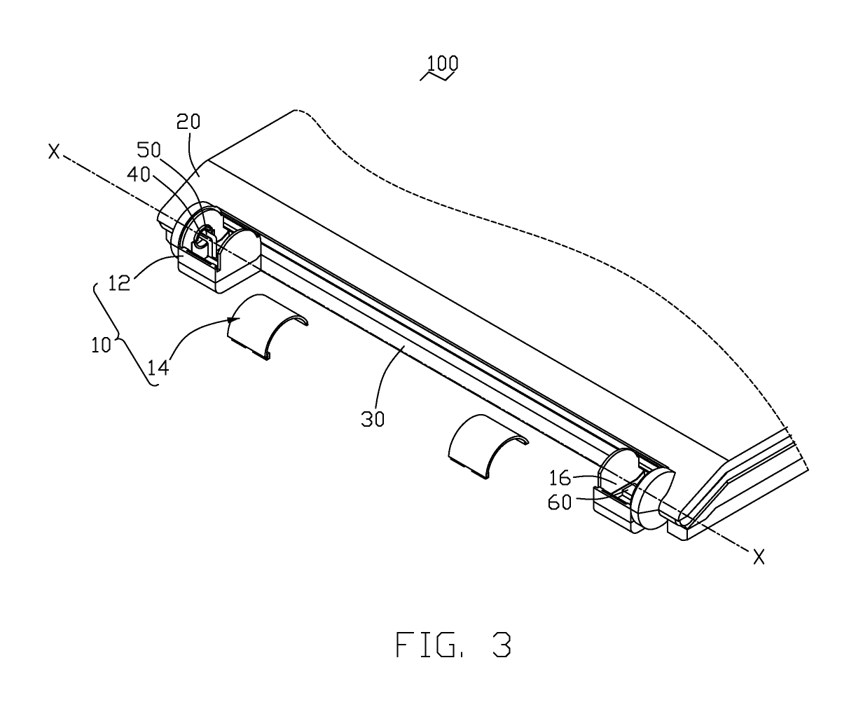

Referring to FIG. 3, some elements of the notebook computer 100, such as a microphone, or a speaker 60 may be installed in the base 12, thus saving space. Further, when the lid 20 of the notebook computer 100 is opened, the speaker 60 may directly face to users, thus the notebook computer 100 may have a good sound effect.

The cover 14 can be slidably engaged with the base 12, for covering the hinge 40, the cables 50, and the speaker 60.

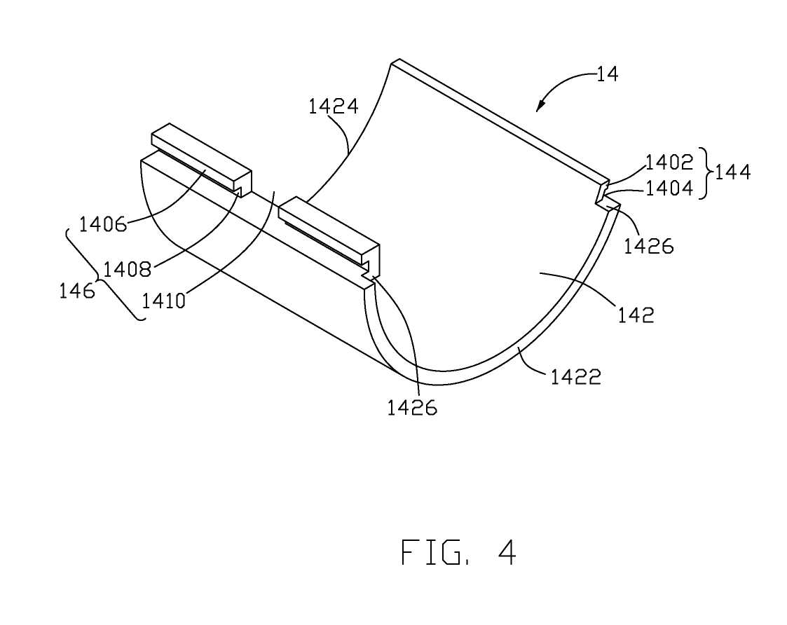

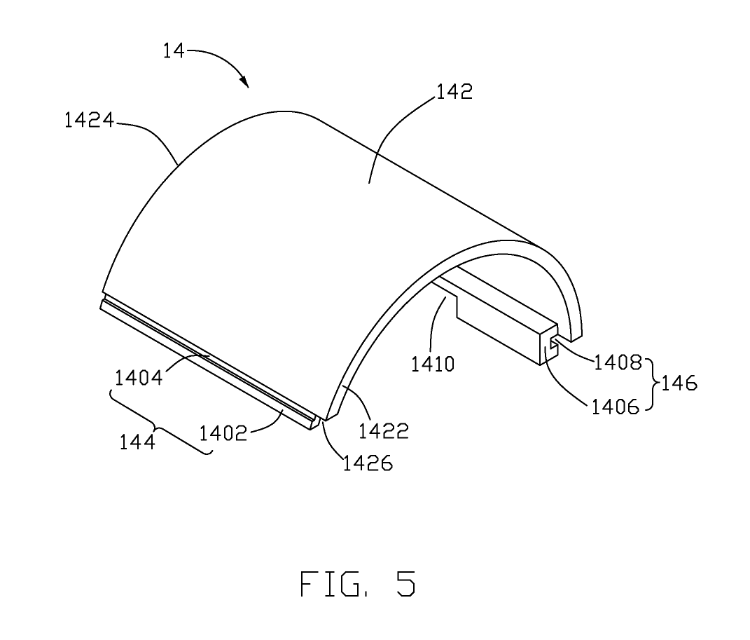

Referring to FIG. 4 and FIG. 5, the cover 14 is generally in a shape of a half cylinder. The cover 14 includes a coping 142, a first fixing portion 144, and a second fixing portion 146. The first fixing portion 144 and the second fixing portion 146 are formed at two opposite edges of the coping 142. The first fixing portion 144 includes a first fixing strip 1402 and a first sliding slot 1404. The first fixing strip 1402 is generally an extension of the coping 142 in a circumferential direction thereof. The first sliding slot 1404 is formed on an outer side of the first fixing strip 1402.

The second fixing portion 146 also includes a second fixing strip 1406 extending from an opposite end of the coping 142 in a circumferential direction thereof and a second sliding slot 1408. The second fixing strip 1406 has a gap 1410 formed in a middle position thereof. The second sliding slot 1408 is formed on an outer side of the second fixing strip 1406 between the second fixing strip 1406 and the coping 142.

The coping 142 of the cover 14 has a first end face 1422 and a second end face 1424 in the axial direction thereof. Two breaches 1426 are symmetrically located at two corners of the coping 142 where the first end face 1422 meets the first fixing portion 144 and the second fixing portion 146 respectively.

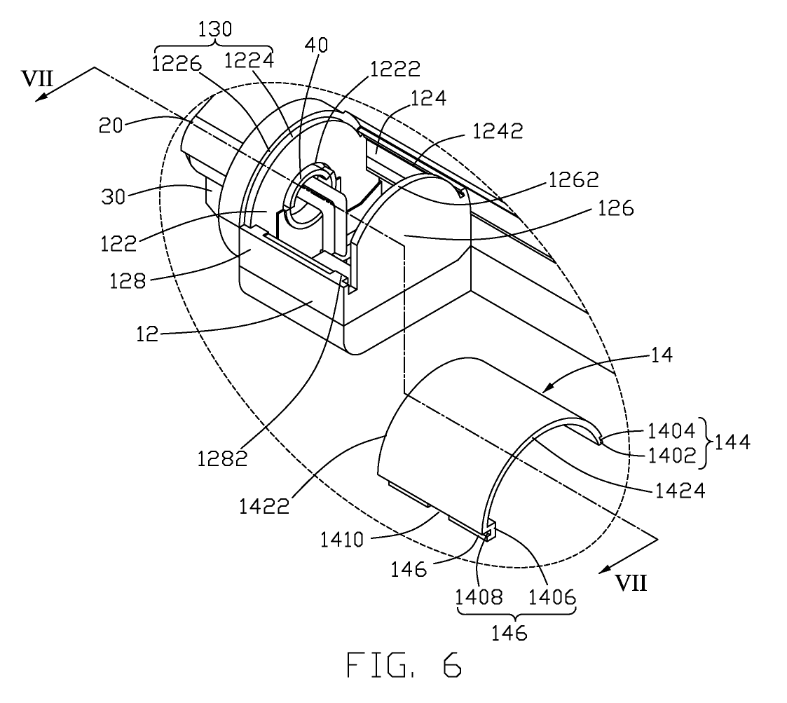

Referring to FIG. 6, the base 12 includes four sidewalls that surround the cavity 16. The four sidewalls include a first supporting wall 122, a first sliding wall 124, a second supporting wall 126, and a second sliding wall 128 connected with each other in series. Both the supporting walls 122, 126 and the two sliding walls 124, 128 are set face to face, respectively.

The two supporting walls 122 and 126 are generally U-shaped with an arc-shaped top end corresponding to the cylindrical coping 142 of the cover 14. The first supporting wall 122 has a hole 1222 set in a middle position thereof. The hinge 40 and the cables 50 are capable of extending through the hole 1222, to be received in the cavity 16.

A first supporting face 1224 and a sustaining face 1226 abut each other to form a step 130 on the top end of the first supporting wall 122. The first supporting face 1224 has an arcuate configuration corresponding to an inner surface of the cylindrical coping 142 of the cover 14. The first supporting face 1224 has a same height with that of a second supporting face 1262, which is formed at a top end of the second supporting wall 126. The sustaining face 1226 is configured for resisting an end face 1422 of the cover 14 when the cover 14 slides on the base 12.

A top end of the first sliding wall 124 appreciably extends inwardly towards the cavity 16 to form a first slide-rail 1242. The first slide-rail 1242 is configured for engaging with the first fixing strip 1402 and the first sliding slot 1404 of the first fixing portion 144. Similarly, the top end of the second sliding wall 128 also appreciably extends inwardly to form a second slide-rail 1282. The second slide-rail 1282 is configured for engaging with the second fixing strip 1406 and the second sliding slot 1408 of the second fixing portion 146. Two entrances are formed where the slide-rails meet the second supporting wall 126.

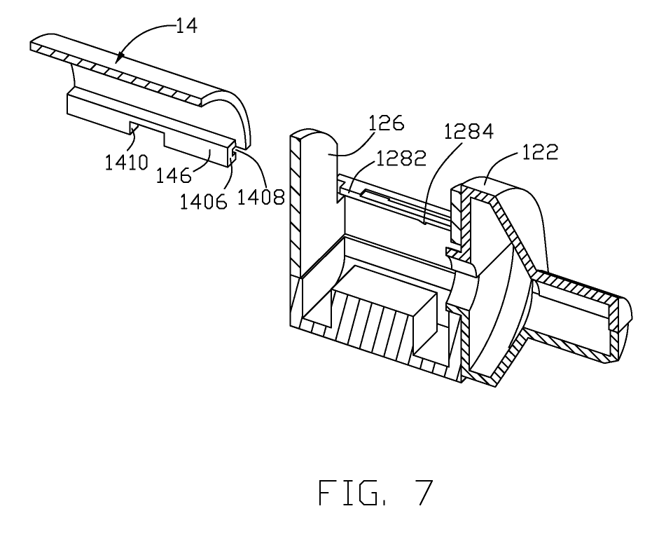

Referring to FIG. 7, a cross-sectional view of the covering assembly 10 taken along a line VII-VII of FIG. 6 is illustrated. A protrusion 1284 is set inside the second slide-rail 1282. The protrusion 1284 is set in a middle position corresponding to the gap 1410 of the second fixing strip 1406, configured for being engaged into the gap 1410 of the second fixing strip 1406, further fixing the cover 14 on the base 12.

When assembling, the breaches 1426 of the cover 14 are set facing the entrances of the slide-rails 1242 and 1282. The cover 14 is driven to slide along the slide-rails 1242 and 1282 in the axial direction X-X to the first supporting wall 122. When the cover 14 moves to a position where the first end face 1422 contacts with the sustaining face 1226, the protrusion 1284 engages in the gap 1410. The cover 14 is further driven to move until the first end face 1422 is engaged with the sustaining face 1226. Thus, the cover 14 is fixed to the base 12, and covering the cables 50 and the hinge 40.

Based on the above covering assembly, the cables 50 that are used for communication between the lid 20 and the main body 30 of the notebook computer 100 are shielded. Additionally, the hinge 40 interconnecting the lid 20 and the main body 30 of the notebook computer 100 are shielded as well. Thus, the cables 50 and the hinge 40 are not exposed to users directly, the cables 50 are shielded from any damage and interference, and working performance of the notebook computer 100 is stabilized. The notebook computer 100 has a better appearance as well. Additionally, the speaker 60 may be installed in the base 12 for saving space, when the lid 20 is open, the speaker 60 may directly face to users, thus the notebook computer 100 may have a good sound effect.

Obviously, the notebook computer is described above only to show an exemplary embodiment of the present covering assembly. Persons skilled in the art may easily apply the covering assembly to other devices with one part pivotally connected to another, for example, cellular phones, portable audio/video players, and so on.

What is claimed is:

1. A covering assembly comprising:
a base, comprising:
a cavity bounded by a plurality of sidewalls;
at least one slide-rail set on the sidewalls;
a hole defined in at least one of the sidewalls, for allowing cables to extend therethrough; and
a protrusion set on the at least one slide-rail; and
a cover slidably mating with the base, the cover comprising:
a coping for covering the cavity;
at least one fixing portion set on one side of the coping, configured for slidably engaging with the at least one slide-rail; and
a gap defined in the at least one fixing portion configured for engaging with the protrusion to prevent the cover withdrawing from the base.

2. The covering assembly as claimed in claim 1, wherein the at least one fixing portion comprises a sliding slot and a fixing strip, the sliding slot being formed on an outer side of the coping and mating with the at least one slide-rail, and the fixing strip being formed at an inner side of the coping.

3. The covering assembly as claimed in claim 1, wherein the protrusion is set on an inner side of the at least one slide-rail facing the cavity.

4. The covering assembly as claimed in claim 1, wherein the sidewalls bounding the cavity comprise a first supporting wall and a second supporting wall, the first supporting wall faces the second supporting wall, wherein the first supporting wall and the second supporting wall respectively has a first supporting face and a second supporting face having configurations corresponding to an inner surface of the coping, opposite ends of the coping being supported on the first and second supporting faces.

5. The covering assembly as claimed in claim 4, wherein the first supporting face and the second supporting face are of a same height.

6. The covering assembly as claimed in claim 5, wherein a step is formed on one of the first supporting wall and the second supporting wall, the step comprises the first supporting face for supporting the cover and a sustaining face for resisting an end face of the cover.

7. The covering assembly as claimed in claim 1, wherein the sidewalls bounding the cavity comprise a pair of sliding walls, the protrusion being set on a top side of one of the sliding walls.

8. A notebook computer comprising:
a main body;
a lid pivotally connecting with the main body;
a plurality of electric cables for communicating the lid with the main body; and
a covering assembly fixed on one side of the main body, for receiving and shielding the cables, the covering assembly comprising:
a base having a cavity with a sidewall therearound, a hole being defined in the sidewall configured for allowing the cables to extend therethrough, the base being fixed on one side of the main body; and
a cover configured for shielding the cavity slidably mated with the base.

9. The notebook computer as claimed in claim 8, further comprising a speaker, wherein the speaker is secured in the cavity.

10. The notebook computer as claimed in claim 8, wherein the cavity is bounded by a plurality of sidewalls, at least one slide-rail is set on the sidewalls, and at least one fixing portion is set on one side of the cover configured for slidably mating with the slide-rail.

11. The notebook computer as claimed in claim 10, wherein the fixing portion comprises a sliding slot and a fixing strip, the sliding slot is formed on an outer side of the cover, the fixing strip is set on an inner side of the cover.

12. The notebook computer as claimed in claim 8, wherein the base comprises a protrusion extending inwardly towards the cavity, and the cover has a gap in a position corresponding to that of the protrusion, the protrusion being engagable with the gap, for fixing the cover on the base in an axial direction of rotation of the lid.

13. The notebook computer as claimed in claim 12, wherein the cavity is bounded by a first supporting wall, a second supporting wall, a first sliding wall, and a second sliding wall, the supporting walls are set face to face, and the sliding walls are set face to face, said sidewall constituting one of the first and second supporting walls.

14. The notebook computer as claimed in claim 13, wherein the first supporting wall and the second supporting wall respectively has a first supporting face and a second supporting face having a configuration corresponding to an inner surface of the cover, opposite ends of the coping being supported on the first and second supporting faces.

15. The notebook computer as claimed in claim 13, wherein a step is formed on one of the first supporting wall and the second supporting wall, the step comprising a sustaining face for resisting an end face of the cover.

16. A notebook computer comprising:
a main body;
a lid connected to one side of the main body and being pivotable with respect to the main body in an axial direction;
a plurality of electric cables for communicating the lid with the main body;
a base being cooperatively constituted by the main body and the lid at said side, the base having a cavity configured for receiving the cables therein; and
a cover configured for shielding the cavity and slidably attached to the base in the axial direction.

17. The notebook computer as claimed in claim 16, further comprising at least one hinge configured for pivotably connecting the main body with the lid, wherein the at least one hinge is accommodated within the cavity.

18. The notebook computer as claimed in claim 16, further comprising another base and another cover slidably attached to the another base, and a battery being mounted to the main body between the covers after the covers are attached to the bases.

19. The notebook computer as claimed in claim 16, wherein the base comprises a pair of sliding walls and a pair of supporting walls cooperatively bounding the cavity, the cover has an arcuate configuration, each of the supporting walls has an arcuate top surface fitting the arcuate configuration of the cover, the cover is capable of sliding along the sliding walls in the axial direction to be securely supported on the top surfaces of the supporting walls.

20. The notebook computer as claimed in claim 19, wherein a top edge of each of the sliding walls extends toward the cavity to form a slide rail, a pair of strips extends from opposite ends of an inner surface of the cover, and each of the strips defines a sliding slot in an outer surface thereof configured for slidably receiving the slide rail.
